(19) United States
(12) Patent Application Publication
(10) Pub. No.: US 2026/0060074 A1
(43) Pub. Date: Feb. 26, 2026

(54) PACKAGE STRUCTURE

(71) Applicant: UNITED MICROELECTRONICS CORP., Hsin-Chu City (TW)

(72) Inventor: Kuang-Hui Tang, Kaohsiung City (TW)

(73) Assignee: UNITED MICROELECTRONICS CORP., Hsin-Chu City (TW)

(21) Appl. No.: 18/900,829

(22) Filed: Sep. 29, 2024

(30) Foreign Application Priority Data
Aug. 26, 2024 (TW) 113131986

(51) Int. Cl. H01L 23/367; H01L 23/00; H01L 23/473; H01L 23/498

(52) U.S. Cl. CPC H01L 23/3675; H01L 23/473; H01L 24/29; H01L 24/32; H01L 24/48; H01L 24/73; H01L 23/49827; H01L 24/33; H01L 2224/29099; H01L 2224/32225; H01L 2224/33181; H01L 2224/48227; H01L 2224/73215; H01L 2224/73265

(57) ABSTRACT

A package structure includes a package substrate. Numerous leads penetrate the package substrate. A top plate is disposed on the package substrate. An extension component extends from the top plate to the package substrate. Four side plates are disposed between the package substrate and the top plate. A die is disposed on the package substrate. The die includes a first surface and a second surface, and the first surface and the second surface are opposite. The extension component is bonded to the first surface of the die through a thermal conductive adhesive. Numerous conductive terminals are disposed on the die and exposed through the first surface. Numerous wires are disposed on the package substrate. Each wire is connected to one of the leads and one of the conductive terminals.

### BACKGROUND OF THE INVENTION

### 1. Field of the Invention

The present invention relates to a package structure, in particular to a package structure that enhances heat dissipation by a coolant or a top plate.

### 2. Description of the Prior Art

In recent years, with the rapid development of electronic technology and the advent of high-tech electronic industries, electronic products that are more user-friendly and have better functions are provided. The electronic products are designed to become lighter, thinner, smaller.

In the semiconductor package technology, quad flat Package (QFP) or quad flat non-leaded package (QFN) has a short signal transferring path and relatively fast signal transmission speed. Therefore, they are major packaging types.

In order to follow the trend of thinness, lightness and multi-function, it is necessary to stack several dies in a limited area in a package structure. However, stacking dies may lead to heat accumulation. Furthermore, gallium nitride wafers are widely used in wireless communication systems. Although the computing performance is improved, a large amount of heat will be accumulated in the package structure during the computing process, thus affecting the operating performance of electronic products.

### SUMMARY OF THE INVENTION

According to a preferred embodiment of the present invention, a QFN structure includes a package substrate. Numerous leads penetrate the package substrate. A top plate is disposed on the package substrate. An extension component extends from the top plate to the package substrate. Four side plates disposed between the package substrate and the top plate. A die is disposed on the package substrate, wherein the die includes a first surface and a second surface, the first surface and the second surface are opposite, and the extension component is bonded to the first surface of the die through a thermal conductive adhesive. Numerous conductive terminals are disposed on the die and exposed through the first surface. Numerous wires are disposed on the package substrate, wherein each of the wires is connected to one of the leads and one of the conductive terminals.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a QFN structure according to a preferred embodiment of the present invention.

FIG. 2 depicts a sectional view taken along line AA′ in FIG. 1 according to a first preferred embodiment of the present invention.

FIG. 3 depicts an enlarged view of a die according to a preferred embodiment of the present invention.

FIG. 4 depicts a sectional view taken along line AA′ in FIG. 1 according to a second preferred embodiment of the present invention.

FIG. 5 depicts a sectional view taken along line AA′ in FIG. 1 according to a third preferred embodiment of the present invention.

### DETAILED DESCRIPTION

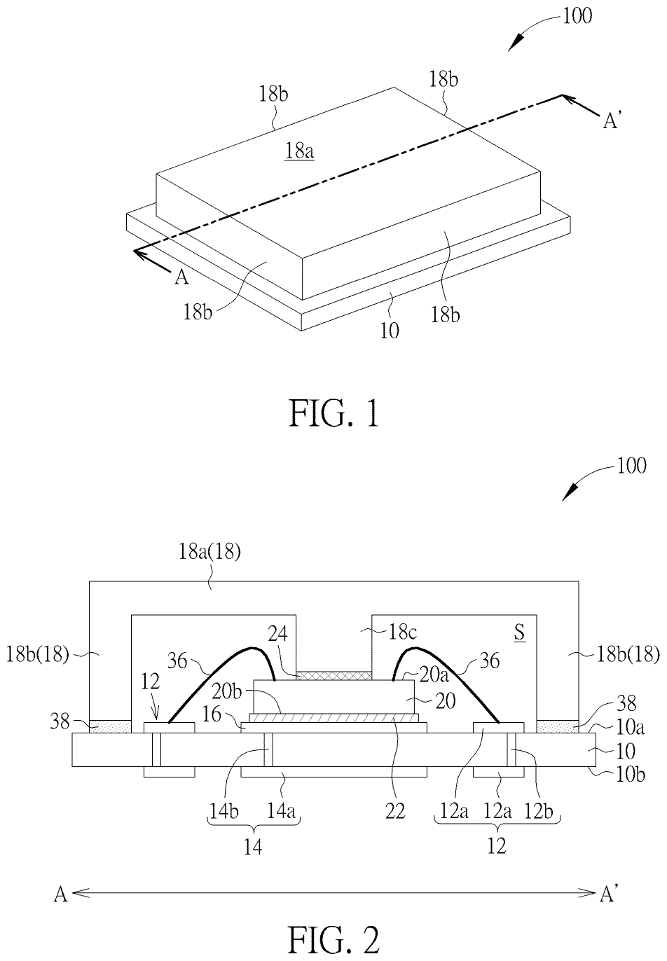

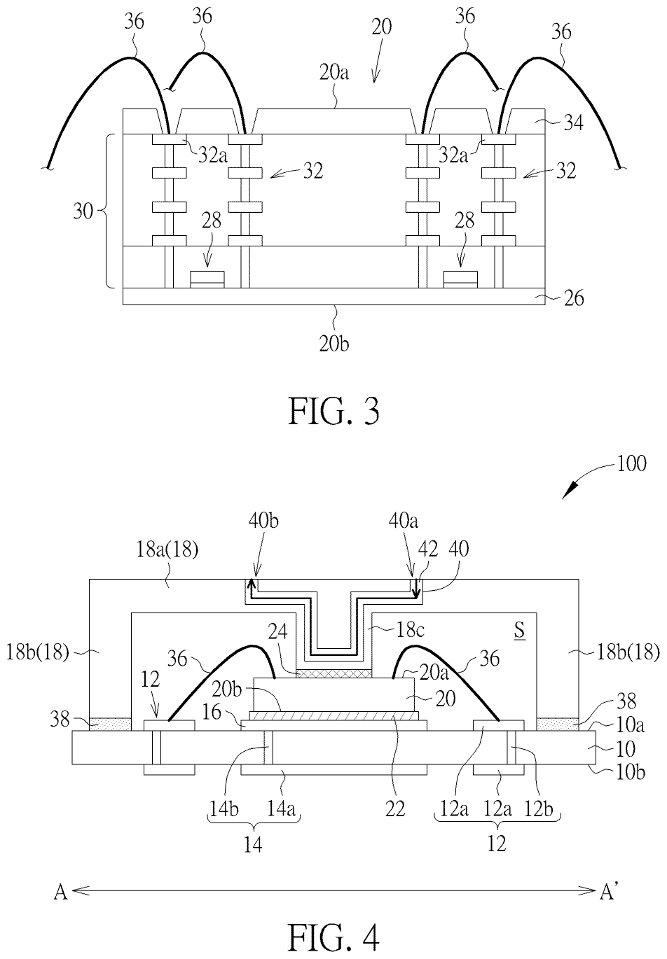

FIG. 1 depicts a QFN structure according to a preferred embodiment of the present invention. FIG. 2 depicts a sectional view taken along line AA′ in FIG. 1 according to a first preferred embodiment of the present invention. FIG. 3 depicts an enlarged view of a die according to a preferred embodiment of the present invention.

As shown in FIG. 1, FIG. 2 and FIG. 3, a package structure 100 of the present invention includes a package substrate 10. The package substrate 10 includes a third surface 10a and a fourth surface 10b. The third surface 10a and the fourth surface 10b are opposite to each other. Numerous leads 12 penetrate the package substrate 10. Each of the leads 12 includes two conductive pads 12a and a connecting element 12b. The two conductive pads 12a respectively contact the third surface 10a and the fourth surface 10b. The connecting element 12b penetrates the package substrate 10 and connects the two conductive pads 12a. Moreover, a metal thermal conductive pad 14 is disposed on the package substrate 10. The metal thermal conductive pad 14 penetrates the package substrate 10 and is disposed on the fourth surface 10b. A die paddle 16 is disposed on the third surface 10a and connected to the metal thermal conductive pad 14. In details, the metal thermal conductive pad 14 includes a metal pad 14a and a connecting element 14b. The metal pad 14a contacts the fourth surface 10b. The connecting element 14b penetrates the package substrate 10. The connecting element 14b connects the metal pad 14a and the die paddle 16.

A top plate 18a is disposed on the package substrate 10. An extension component 18c extends from the top plate 18a to the package substrate 10. Four side plates 18b are disposed between the package substrate 10 and the top plate 18a. The top plate 18a, the four side plates 18b and the extension component 18c together form a package case 18. In addition, the package substrate 10, the side plate 18b, the top plate 18a and the extension component 18c together define an accommodation space S. Air is filled in the accommodation space S. Moreover, a die 20 is disposed on the package substrate 10 and in the accommodation space S. The die 20 includes a first surface 20a and a second surface 20b. The first surface 20a and the second surface 20b are opposite to each other. The second surface 20b of the die 20 is attached to the die paddle 16 through a first adhesive 22. The first surface 20a is the front side of the die 20, and the second surface 20b is the back side of the die 20. It is noteworthy that the extension component 18c is bonded to the first surface 20a of the die 20 through a thermal conductive adhesive 24. The thermal conductive adhesive 24 can conduct the heat generated by the die 20 to the extension component 18c. Later, the heat can be conducted to the top plate 18a through the extension component 18c for heat dissipation.

The die 20 includes a substrate 26. An active device 28 such as a transistor is disposed on the substrate 26. Moreover, a dielectric material layer 30 covers the substrate 26. The dielectric material layer 30 includes silicon oxide, silicon oxynitride or low dielectric coefficient materials. Numerous metal connections 32 are disposed in the dielectric material layer 30. Metal connections 32 include aluminum, copper, tungsten or other conductive materials. A protective layer 34 covers the dielectric material layer 30 and the metal connections 32 are exposed from the protective layer 34. The exposed metal connections 32 serve as numerous conductive terminals 32a. The protective layer 34 includes silicon oxide or silicon nitride. The metal connections 32 are electrically connected to the active device 28 to input or output signals into active device 28. The top surface of the protective layer 34 is the first surface 20a of the die 20. The bottom surface of the substrate 26 is the second surface 20b of the die 20. There is not any conductive terminal which is exposed on the second surface 20b of the die 20. Moreover, numerous wires 36 are disposed on the package substrate 10. Each wire 36 is connected to one lead 12 and one conductive terminal 32a. In FIG. 2, only two wires 36 are used as an illustration. Practically, the number of wires 36 is adjusted according to the number of conductive terminals 32a. Furthermore, wires 36 include gold, silver, copper or aluminum. It can be seen from the structure of die 20 that the thermal conductive adhesive 24 contacts the first surface 20a which has the conductive terminal 32a thereon. That is, the extension component 18c receives heat from the first surface 20a having the conductive terminal 32a.

As shown in FIG. 2, in the first preferred embodiment, the top plate 18a, the side plates 18b and the extension component 18c are formed monolithically. Therefore, the top plate 18a, the side plates 18b and the extension component 18c are made of the same material. The top plate 18a, the side plates 18b and the extension component 18c include ceramic, metal, resin or glass. The package substrate 10 may also include ceramic, metal, resin or glass. Moreover, the four side plates 18b are bonded to the package substrate 10 through the second adhesive 38. In details, an end of each of the side plates 18b is bonded to the package substrate 10 through the second adhesive 38. The first adhesive 22 and the second adhesive 38 include high molecular polymer, such as epoxy resin. The leads 12, the metal thermal conductive pad 14, and the die paddle 16 include conductive materials such as copper, copper alloy, iron-nickel alloy or other conductive materials.

FIG. 4 depicts a sectional view taken along line AA′ in FIG. 1 according to a second preferred embodiment of the present invention. As shown in FIG. 4, In addition to dissipating heat through the top plate 18a, the package structure 100 of the second preferred embodiment can also dissipate heat through a coolant 42. For example, a channel 40 is disposed in the top plate 18a and the extension component 18c. An inlet 40a and an outlet 40b are respectively disposed at two ends of the channel 40. The inlet 40a and the outlet 40b are located in the top plate 18a. The coolant 42 is filled in the channel 40. The coolant 42 that has not absorbed the heat of the die 20 can be input into the channel 40 through the inlet 40a. After the coolant 42 absorbs heat from the die 20, the coolant 42 leaves the channel 40 through the outlet 40b. The coolant 42 circulates continuously; therefore, the heat dissipation of the die 20 is accelerated. The channel 40, the inlet 40a, the outlet 40b and the coolant 42 form a heat dissipation device. According to a preferred embodiment of the present invention, the coolant 42 may include water or a non-conductive liquid. The non-conductive liquid includes DOWSIL™ immersion cooling liquid. In the second preferred embodiment, except for adding the channel 40 and the coolant 42, other devices are the same as those in the first preferred embodiment and will not be described again.

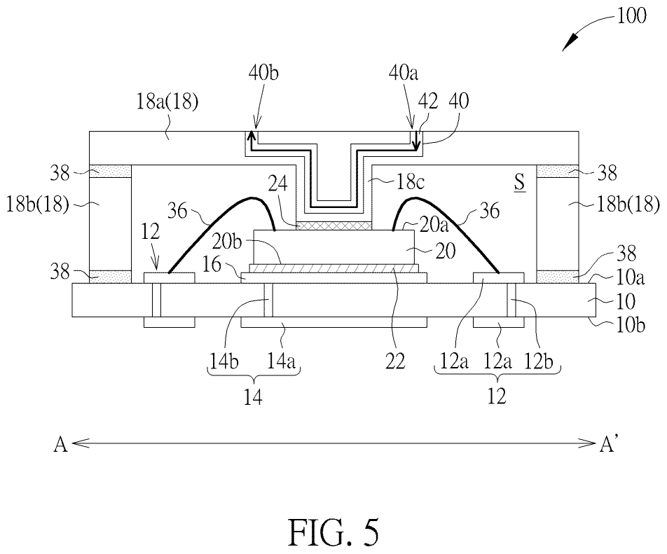

FIG. 5 depicts a sectional view taken along line AA′ in FIG. 1 according to a third preferred embodiment of the present invention.

As shown in FIG. 5, the difference between the second preferred embodiment and the third preferred embodiment is that the top plate 18a and the side plates 18b are not formed monolithically. Therefore, one end of each side plate 18b is bonded to the top plate 18a through the second adhesive 38. Moreover, because the top plate 18a and the side plates 18b are not formed monolithically, the materials of the top plate 18a and the side plates 18b can be the same or different. Furthermore, materials of each of the side plates 18b can be the same or different. In the third preferred embodiment, the top plate 18a and the extension component 18c are still formed monolithically, therefore the top plate 18a and the extension component 18c are made of the same material. Similarly, the top plate 18a and extension component 18c include ceramic, metal, resin or glass. Each of the four side plates may respectively include ceramic, metal, resin or glass. Other devices are the same as those in the second preferred embodiment and will not be described again.

As shown in FIG. 1, FIG. 2 and FIG. 3, the fabricating method of the package structure 100 of the present invention include providing a package substrate 10. A metal thermal conductive pad 14 and a die paddle 16 are disposed on the package substrate 10. Then, the second surface 20b of the die 20 is attached to the die paddle 16 through the first adhesive 22. Later, numerous wires 36 are formed. Each of the wires 36 respectively connects to a lead 12 on the package substrate 10 and a conductive terminal 32a on the die 20. Next, a package case 18 is provided. The package case 18 includes a top plate 18a, the four side plates 18b and an extension component 18c. Subsequently, a thermal conductive adhesive 24 is applied on the first surface 20a of the die 20, and a second adhesive 38 is applied to the side plates 18b. After that, the package case 18 is put to cover on the package substrate 10. Then, the second adhesive 38 and the thermal conductive adhesive 24 are cured. Now, the package structure 100 in the first preferred embodiment is completed. The package structure 100 in the second preferred embodiment and the third preferred embodiment can also be manufactured by the same process of the first preferred embodiment. Except that a channel 40 for a coolant is provided in the package case 18. Moreover, the side plates 18b in third preferred embodiment need to be bonded to the top plate 18a.

The present invention specifically provides an extension component 18c to conduct the heat generated by the die 20 to the top plate 18a. In this way, the heat dissipation efficiency of the packaging structure 100 can be increased. Furthermore, based on product requirements, a channel 40 can be disposed in the extension component 18c and the top plate 18a. By injecting the coolant 42 in the channel 40, the heat generated by the die 20 is removed more quickly. Moreover, the conventional heat dissipation device is set outside the package case, therefore, its heat dissipation performance is poor. The heat dissipation device of the present invention is disposed inside the packaging case 18 which is closer to the die 20. Therefore, the package structure of the present invention has a better heat dissipation performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package structure, comprising:
a package substrate;
a plurality of leads penetrating the package substrate;
a top plate disposed on the package substrate;
an extension component extending from the top plate to the package substrate;
four side plates disposed between the package substrate and the top plate;
a die disposed on the package substrate, wherein the die comprises a first surface and a second surface, the first surface and the second surface are opposite, and the extension component is bonded to the first surface of the die through a thermal conductive adhesive;
a plurality of conductive terminals disposed on the die and exposed through the first surface; and
a plurality of wires, wherein each of the plurality of wires is connected to one of the plurality of leads and one of the plurality of conductive terminals.

2. The package structure of claim 1, wherein the package substrate comprises a third surface and a fourth surface, and the third surface and the fourth surface are opposite to each other.

3. The package structure of claim 2, further comprising:
a metal thermal conductive pad penetrating the package substrate and disposed on the fourth surface; and
a die paddle disposed on the third surface and connected to the metal thermal conductive pad, wherein the second surface of the die is attached to the die paddle through a first adhesive.

4. The package structure of claim 2, wherein each of the plurality of leads is respectively disposed on the third surface and the fourth surface of the package substrate.

5. The package structure of claim 1, further comprising:
a channel disposed in the top plate and the extension component;
an inlet and an outlet respectively disposed at two ends of the channel, wherein the inlet and the outlet are disposed in the top plate; and
a coolant filling the channel.

6. The package structure of claim 5, wherein the coolant comprises water.

7. The package structure of claim 5, wherein the coolant comprises non-conductive liquid.

8. The package structure of claim 7, wherein the coolant comprises DOWSIL™ immersion cooling liquid.

9. The package structure of claim 1, wherein two ends of each of the side plates are respectively connected to the top plate and the package substrate through a second adhesive.

10. The package structure of claim 9, wherein the top plate, the side plates and the extension component respectively comprise ceramic, metal, resin or glass.

11. The package structure of claim 1, wherein the top plate, the side plates and the extension component are formed monolithically.

12. The package structure of claim 11, wherein the top plate, the side plates and the extension component comprise ceramic, metal, resin or glass.

13. The package structure of claim 1, wherein there is no conductive terminal exposed from the second surface of the die.

14. The package structure of claim 1, wherein the package substrate, the side plates, the top plate and the extension component together define an accommodation space, the die is disposed in the accommodation space, and air fills up the accommodation space.
